(19) United States
(12) Patent Application Publication
(10) Pub. No.: US 2017/0040521 A1
(43) Pub. Date: Feb. 9, 2017

(54) THERMOELECTRIC CONVERSION DEVICE

(71) Applicant: Industrial Technology Research Institute, Hsinchu (TW)

(72) Inventors: Chun-Kai Lin, Yilan County (TW); Rei-Cheng Juang, Hsinchu City (TW); Yi-Ray Chen, Hsinchu City (TW); Kuang-Yao Chen, Hualien County (TW); Chien-Hsuan Yeh, Miaoli County (TW); Hsiao-Hsuan Hsu, Taipei City (TW); Yu-Li Lin, Chiayi City (TW)

(73) Assignee: Industrial Technology Research Institute, Hsinchu (TW)

(21) Appl. No.: 15/298,253

(22) Filed: Oct. 20, 2016

Related U.S. Application Data
(62) Division of application No. 13/893,348, filed on May 14, 2013.

(30) Foreign Application Priority Data
Nov. 23, 2012 (TW) 101143958

(51) Int. Cl. H01L 35/30; G01J 5/12; H01L 35/02

(52) U.S. Cl. CPC H01L 35/30; H01L 35/02; G01J 5/12

(57) ABSTRACT

A thermoelectric conversion device and a selective absorber film are provided. The thermoelectric conversion device includes at least one first selective absorber film, a cold terminal substrate, at least one first thermoelectric element pair, a first conductive substrate and a second conductive substrate. The first selective absorber film non-contactly absorbs a preset limited wavelength band of heat radiation. The first thermoelectric element pair is disposed between the first selective absorber film and the cold terminal substrate, and includes a first N-type thermoelectric element and a first P-type thermoelectric element. The first conductive substrate is disposed between the cold terminal substrate and the first N-type thermoelectric element. The second conductive substrate is disposed between the cold terminal substrate and the first P-type thermoelectric element. The first thermoelectric element pair generates current to perform power generation in response to temperature difference between the first selective absorber film and the cold terminal substrate.

### CROSS-REFERENCE TO RELATED APPLICATION

This application is a divisional application of U.S. application Ser. No. 13/893,348, filed on May 14, 2013, now pending, which claims the priority benefit of Taiwan application serial no. 101143958, filed on Nov. 23, 2012. The entirety of each of the above-mentioned patent applications is hereby incorporated by reference herein and made a part of this specification.

### TECHNICAL FIELD

The disclosure relates to a thermoelectric conversion device utilizing a selective absorber film as a hot terminal.

### BACKGROUND

Due to the problem of energy shortage, development of renewable energy technologies has become an important topic. Thermoelectric conversion technology is a new renewable energy technology today which is able to directly convert between heat energy and electrical energy. The thermoelectric conversion technology is to achieve the effect of energy conversion between heat energy and electrical energy by carrier movement in a thermoelectric material, and no mechanical moving part is required in the energy conversion process. Therefore, the technology has advantages of small volume, no noise, no vibration, and environmental friendliness, and also has application potential in fields such as temperature difference electricity generation, waste heat recycling, electronic cooling and air conditioning system. In recent years, the thermoelectric conversion technology has received enormous attention from research institutions in various countries and considerable efforts have been invested in research and development. In addition to development of materials, application of thermoelectric technology has also been the focus of research interest.

With respect to waste heat recycling systems currently used in industry, large-scale waste heat recycling systems such as cogeneration and hot air recycling and preheating are common. However, there are many cases where sensible heat of a finished product cannot be recycled and reused, for example, a metal smelter or a metal heat treatment plant. Both temperature unifomiity and cooling rate of a high-temperature metal object may affect quality of a finished metal product, and in addition, limited space for production line is less favorable for installation of a large-scale waste heat recycling device. Accordingly, even if it is known that a huge amount of waste heat is generation in a continuous casting production line, at present there is no effective method of recycling waste heat therefor. The problem that the sensible heat of finished product is difficult to recycle occurs not only in a metal smelter, but also in a foundry. Therefore, how to effectively recycle and reuse the waste heat in industry is also a significant issue.

### SUMMARY

The disclosure provides a thermoelectric conversion device including at least one first selective absorber film, a cold terminal substrate, at least one thermoelectric element pair, a first conductive substrate and a second conductive substrate. The first selective absorber film is for non-contactly absorbing a preset limited wavelength band of heat radiation. The thermoelectric element pair is disposed between the first selective absorber film and the cold terminal substrate, and the thermoelectric element pair includes a first N-type thermoelectric element and a first P-type thermoelectric element. The first conductive substrate is disposed between the cold terminal substrate and the first N-type thermoelectric element. The second conductive substrate is disposed between the cold terminal substrate and the first P-type thermoelectric element, wherein the thermoelectric element pair generates a current to perform power generation according to temperature difference between the first selective absorber film and the cold terminal substrate.

Several exemplary embodiments accompanied with figures are described in detail below to further describe the disclosure in details.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIG. 1 is a schematic diagram illustrating a thermoelectric conversion device according to an exemplary embodiment of the disclosure.

FIG. 2 is a cross-sectional diagram illustrating a selective absorber film 110 according to the first exemplary embodiment of the disclosure.

FIG. 3 illustrates a reflectance spectrum of Tiₓ/TiN₁₋ₓ with a fixed film thickness and changing metal volume fractions according to the first exemplary embodiment of the disclosure.

FIG. 4 illustrates a reflectance spectrum of Tiₓ/TiN₁₋ₓ with a fixed metal volume fraction and changing film thicknesses according to the first exemplary embodiment of the disclosure.

FIG. 5 illustrates a reflectance spectrum of Niₓ/NiO₁₋ₓ with a fixed film thickness and changing metal volume fractions according to the first exemplary embodiment of the disclosure.

FIG. 6 illustrates a reflectance spectrum of Niₓ/NiO₁₋ₓ with a fixed metal volume fraction and changing film thicknesses according to the first exemplary embodiment of the disclosure.

FIG. 7 illustrates a reflectance spectrum of Crₓ/(Cr₂O₃)₁₋ₓ with a fixed film thickness and changing metal volume fractions according to the first exemplary embodiment of the disclosure.

FIG. 8 illustrates a reflectance spectrum of Crₓ/(Cr₂O₃)₁₋ₓ with a fixed metal volume fraction and changing film thicknesses according to the first exemplary embodiment of the disclosure.

FIG. 9 illustrates a reflectance spectrum of Wₓ/(WO₃)₁₋ₓ with a fixed film thickness and changing metal volume fractions according to the first exemplary embodiment of the disclosure.

FIG. 10 illustrates a reflectance spectrum of Wₓ/(WO₃)₁₋ₓ with a fixed metal volume fraction and changing film thicknesses according to the first exemplary embodiment of the disclosure.

FIG. 11 is a cross-sectional diagram illustrating the selective absorber film 110 according to the second exemplary embodiment of the disclosure.

FIG. 12 illustrates a reflectance spectrum of Tiₓ/TiN₁₋ₓ with a fixed film thickness and changing metal volume fractions according to the second exemplary embodiment of the disclosure.

FIG. 13 illustrates a reflectance spectrum of Tiₓ/TiN₁₋ₓ with a fixed metal volume fraction and changing film thicknesses according to the second exemplary embodiment of the disclosure.

FIG. 14 illustrates a reflectance spectrum of Niₓ/NiO₁₋ₓ with a fixed film thickness and changing metal volume fractions according to the second exemplary embodiment of the disclosure.

FIG. 15 illustrates a reflectance spectrum of Niₓ/NiO₁₋ₓ with a fixed metal volume fraction and changing film thicknesses according to the second exemplary embodiment of the disclosure.

FIG. 16 illustrates a reflectance spectrum of Crₓ/(Cr₂O₃)₁₋ₓ with a fixed film thickness and changing metal volume fractions according to the second exemplary embodiment of the disclosure.

FIG. 17 illustrates a reflectance spectrum of Crₓ/(Cr₂O₃)₁₋ₓ with a fixed metal volume fraction and changing film thicknesses according to the second exemplary embodiment of the disclosure.

FIG. 18 illustrates a reflectance spectrum of Wₓ/(WO₃)₁₋ₓ with a fixed film thickness and changing metal volume fractions according to the second exemplary embodiment of the disclosure.

FIG. 19 illustrates a reflectance spectrum of Wₓ/(WO₃)₁₋ₓ with a fixed metal volume fraction and changing film thicknesses according to the second exemplary embodiment of the disclosure.

### DETAILED DESCRIPTION OF DISCLOSED EMBODIMENTS

The thermoelectric conversion device in the disclosure non-contactly absorbs a limited wavelength band of heat radiation through the selective absorber film, and then converts the same into electrical energy by using temperature difference between a hot terminal and a cold terminal, thereby increasing the recycling rate of waste heat and further achieving the effect of waste heat recycling and the goal of energy conservation and carbon reduction.

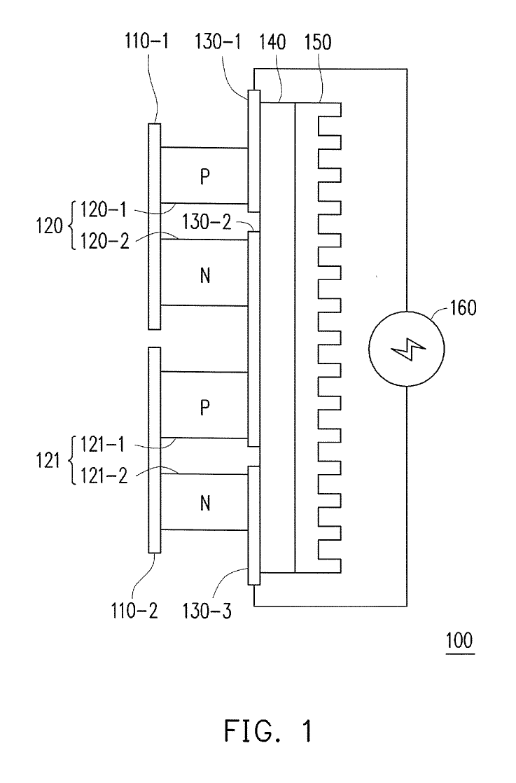

FIG. 1 is a schematic diagram illustrating a thermoelectric conversion device according to an exemplary embodiment of the disclosure. Referring to FIG. 1, a thermoelectric conversion device 100 includes selective absorber films 110-1 and 110-2, thermoelectric element pairs 120 and 121, conductive substrates 130-1, 130-2 and 130-3, a cold terminal substrate 140, a heat dissipation device 150 and a power system 160. The thermoelectric element pair 120 includes a P-type thermoelectric element 120-1 and an N-type thermoelectric element 120-2, and the thermoelectric element pair 121 includes a P-type thermoelectric element 121-1 and an N-type thermoelectric element 121-2. For clearness and simplicity, in the present embodiment, FIG. 1 showing the selective absorber films 110-1 and 110-2, the thermoelectric element pairs 120 and 121, and the conductive substrates 130-1 and 130-3 is provided for illustration. However, the disclosure is not limited thereto.

Still referring to FIG. 1, the thermoelectric element pair 120 is disposed between the selective absorber film 110-1 and the cold terminal substrate 140. The conductive substrates 130-1 and 130-2 are disposed, respectively, between the P-type thermoelectric element 120-1 and the cold terminal substrate 140, and between the N-type thermoelectric element 120-2 and the cold terminal substrate 140. Similarly, the thermoelectric element pair 121 is disposed between the selective absorber film 110-2 and the cold terminal substrate 140. The conductive substrates 130-2 and 130-3 are disposed, respectively, between the P-type thermoelectric element 121-1 and the cold terminal substrate 140, and between the N-type thermoelectric element 121-2 and the cold terminal substrate 140. The P-type thermoelectric elements and the N-type thermoelectric elements in the thermoelectric element pairs 120 and 121 are, for example, alternately arranged in series. The word alternately means that any two adjacent thermoelectric elements are different in type.

For example, as shown in FIG. 1, the N-type thermoelectric element 120-2 and P-type thermoelectric element 120-1 are adjacent in the thermoelectric element pair 120, wherein the N-type thermoelectric element 120-2 in the thermoelectric element pair 120 shares the conductive substrate 130-2 with the P-type thermoelectric element 121-1 in the adjacent thermoelectric element pair 121. Accordingly, the thermoelectric element pairs 120 and 121 are connected in series with each other, and form a circuit loop with the power system 160 via, respectively, the conductive substrate 130-1 and the conductive substrate 130-3. For example, the conductive substrate 130-1 and the conductive substrate 130-3 are electrically connected with the power system 160. The heat dissipation device 150 is disposed on the cold terminal substrate 140, so that the cold terminal substrate 140 achieves effects of temperature reduction and heat dissipation to maintain a temperature difference from a hot terminal substrate 105. The heat dissipation device 150 may be a heat sink, a fan or a water-cooling system, but is not limited thereto.

In the thermoelectric conversion device 100, after the selective absorber films 110-1 and 110-2 respectively absorb heat radiation emitted from a heat source, temperature differences are formed between the selective absorber films 110-1, 110-2 and the cold terminal substrate. When the thermoelectric element pairs 120 and 121 are in the state of temperature difference, electric holes having positive charges in the P-type thermoelectric element 120-1 move through the conductive substrate 130-1 toward the N-type thermoelectric element 121-2, while electric holes having positive charges in the P-type thermoelectric element 121-1 move through the conductive substrate 130-2 toward the N-type thermoelectric element 120-2, so as to generate a current, wherein the current is used to perform power generation via the power system 160 in the path.

It is worth noting that in the present embodiment, the selective absorber film 110 non-contactly absorbs a specific wavelength band of heat radiation emitted from the heat source. The specific wavelength band in which heat radiation is absorbed by the selective absorber film 110 is an infrared light (IR) wavelength band. The selective absorber film 110 has high absorptivity in a near-infrared light (NIR) wavelength band in the range of 1.5 μm˜3 μm, and has a property of high reflectivity in a mid-infrared light (MIR) wavelength band of more than 5 μm. An absorption wavelength range of the selective absorber film 110 can be adjusted by changing a metal volume fraction (MVF) or film thickness of the selective absorber film 110 (details thereof will be described later), such that the selective absorber film 110 efficiently absorbs the heat source in different IR wavelength ranges.

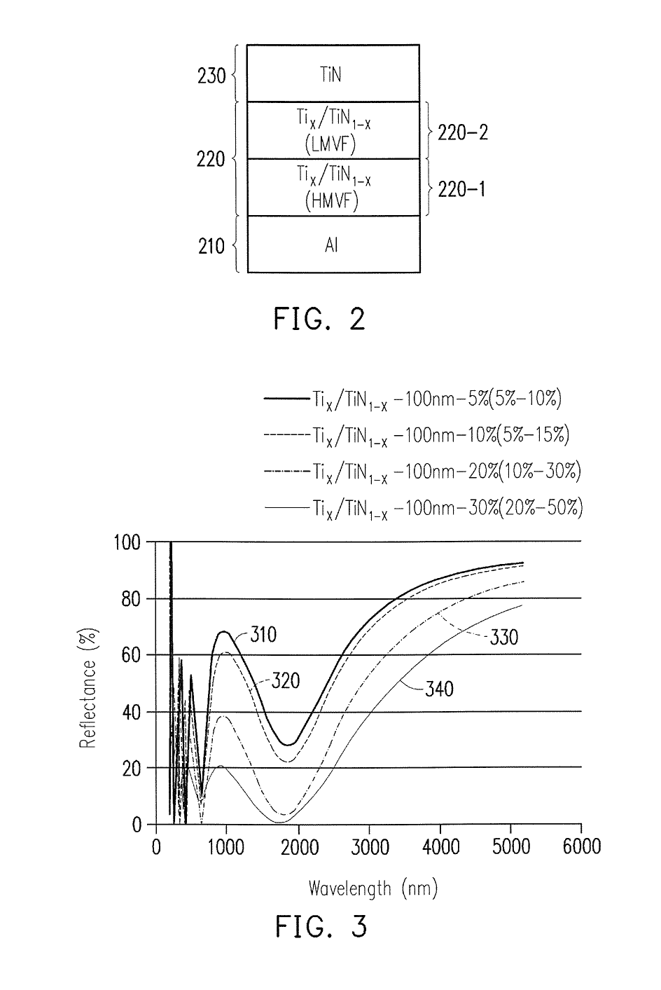

FIG. 2 is a cross-sectional diagram illustrating the selective absorber film 110 according to the first exemplary embodiment of the disclosure. Referring to FIG. 2, first of all, a common, temperature tolerant reflective substrate 210 is provided in the selective absorber film 110 as a hot terminal heat absorption substrate. The reflective substrate 210 consists of materials such as copper (Cu), aluminum (Al), titanium (Ti), or stainless steel (SS). In the present embodiment, Al is employed as the reflective substrate 210 in the selective absorber film 110, but does not intend to limit the disclosure. Next, a ceramic-metal (cermet) film 220 is fabricated on the reflective substrate 210. A metal target of the cermet film 220 is made of materials such as Al, Ti, SS, tungsten (W), nickel (Ni) or chromium (Cr), and is deposited as a metal film or nitride film, oxide film or oxynitride film by introducing corresponding reacting gases (N2, O2). For example, the cermet film 220 is a titanium/titanium-nitride film, a nickel/nickel-oxide film, a chromium/chromium-oxide film, or a tungsten/tungsten-oxide film, but is not limited thereto.

It is worth noting that the cermet film 220 in the present embodiment consists of multiple cermet composite films with different metal volume fractions (MVF) or with different film thicknesses. Accordingly, the IR wavelength band of heat radiation in the optimum absorption range is obtained through adjustment of the metal volume fractions or film thicknesses of ;the cermet composite films. In the present embodiment, a two-layer titanium/titanium-nitride (Tiₓ/TiN₁₋ₓ) film is employed as the cermet film 220 of the selective absorber film 110, but does not intend to limit the disclosure. In the two-layer Tiₓ/TiN₁₋ₓ film, metal volume fraction is used to represent different degrees of nitridation of each cermet composite film. In the present embodiment, Tiₓ/TiN₁₋ₓ films having a high (H) metal volume fraction and a low (L) metal volume fraction are employed as the cermet film 220, wherein the high metal volume fraction and the low metal volume fraction have a gradient relationship. The Tiₓ/TiN₁₋ₓ film 220-1 having the high metal volume fraction is disposed on the reflective substrate 210, the Tiₓ/TiN₁₋ₓ film 220-2 having the low metal volume fraction is disposed on the Tiₓ/TiN₁₋ₓ film 220-1 having the high metal volume fraction. Finally, a fully nitridized or oxidized layer is added to the top as an anti-reflection (AR) layer 230 (i.e. the anti-reflection (AR) 230 is disposed on the Tiₓ/TiN₁₋ₓ film 220-2 having the low metal volume fraction), wherein materials of a metal target of the anti-reflection layer 230 are the same as the materials of the metal target of the cermet film 220. For example, while the cermet film 220 is Tiₓ/TiN₁₋ₓ, the anti-reflection layer 230 is TiN.

TABLE 1

| | | Optimum | |
|---|---|---|---|
| Two-layer | | Range of Metal | Optimum Range of Film |
| Absorber Film | | Volume Fraction | Thickness of Each Layer |
| Tiₓ/TiN₁₋ₓ | LMVF | 5%~20% | 50 nm~100 nm |
| | HMVF | 10%~50% | 50 nm~100 nm |
| Niₓ/NiO₁₋ₓ | LMVF | 5%~20% | 50 nm~200 nm |
| | HMVF | 10%~30% | 50 nm~200 nm |
| Crₓ/(Cr₂O₃)₁₋ₓ | LMVF | 5%~10% | 50 nm~200 nm |
| | HMVF | 10%~30% | 50 nm~200 mn |
| Wₓ/(WO₃)₁₋ₓ | LMVF | 5%~20% | 50 nm~250 mn |
| | HMVF | 10%~50% | 50 nm~250 mn |

FIG. 3 illustrates a reflectance spectrum of Tiₓ/TiN₁₋ₓ with a fixed film thickness and changing metal volume fractions according to the first exemplary embodiment of the disclosure. The film thickness is fixed to 100 nm, and proportion of metal volume fraction of each layer of film is changed, thereby obtaining four data curves 310, 320, 330 and 340, as shown in FIG. 3, wherein the ranges from low (L) metal volume fraction to high (H) metal volume fraction (LMVF %-HMVF %) include, respectively, 5%-10%, 5%-15%, 10%-30%; and 20%-50%. With the same film thickness, the four data curves 310, 320, 330 and 340 all satisfy the characteristic of having high absorptivity in the wavelength range of 1.5 μm-3 μm. Therefore, as shown in Table 1, under the condition with the two-layer Tiₓ/TiN₁₋ₓ, the range of HMVF satisfying the disclosure is 10%-50% and the range of LMVF satisfying the disclosure is 5%-20%.

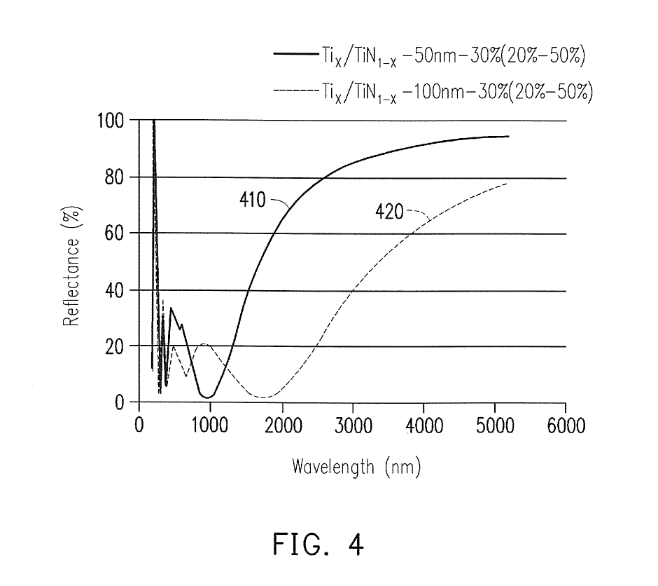

FIG. 4 illustrates a reflectance spectrum of Tiₓ/TiN₁₋ₓ with a fixed metal volume fraction and changing film thicknesses according to the first exemplary embodiment of the disclosure. The range from low (L) metal volume fraction to high (H) metal volume fraction (LMVF %-HMVF %) is fixed to 20%-50%, and the film thicknesses of each layer are changed to from 50 nm to 100 nm, thereby obtaining two data curves 410 and 420, as shown in FIG. 4. With the same proportion of film metal volume fraction, the two data curves 410 and 420 satisfy the characteristic of having high absorptivity in the wavelength range of 1.5 μm-3 μm. Therefore, as shown in Table 1, under the condition with the two-layer Tiₓ/TiN1, the range of film thickness of HMVF satisfying the disclosure is 50 nm˜100 nm and the range of film thickness of LMVF satisfying the disclosure is 50 nm˜100 nm.

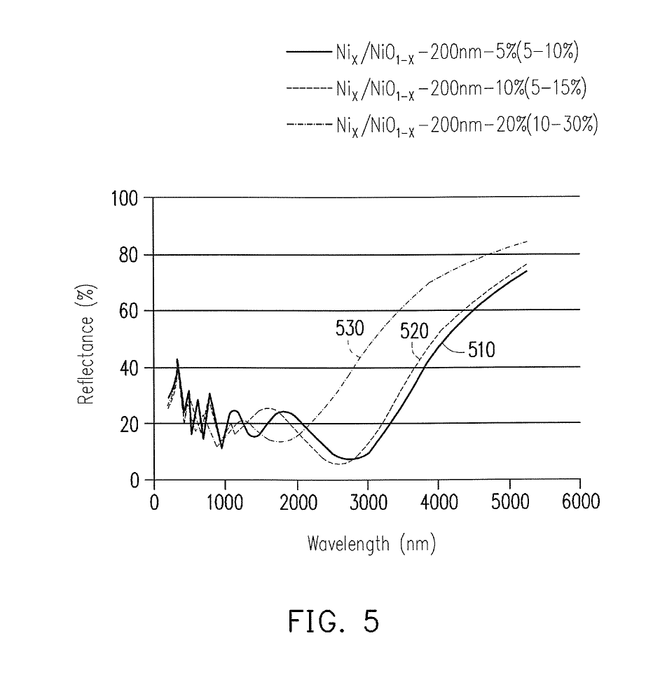

FIG. 5 illustrates a reflectance spectrum of Niₓ/NiO₁₋ₓ with a fixed film thickness and changing metal volume fractions according to the first exemplary embodiment of the disclosure. The film thickness is fixed to 200 nm, and the range from low (L) metal volume fraction to high (H) metal volume fraction (LMVF %-HMVF %) is changed, thereby obtaining three data curves 510, 520 and 530, as shown in FIG. 5, wherein the ranges of metal volume fraction include, respectively, 5%-10%, 5%-15%, and 10%-30%. With the same film thickness, the three data curves 510, 520 and 530 all satisfy the characteristic of having high absorptivity in the wavelength range of 1.5 μm-3 μm. Therefore, as shown in Table 1, under the condition with the two-layer Niₓ/NiO₁₋ₓ, the range of HMVF satisfying the disclosure is 10%-30% and the range of LMVF satisfying the disclosure is 5%-20%.

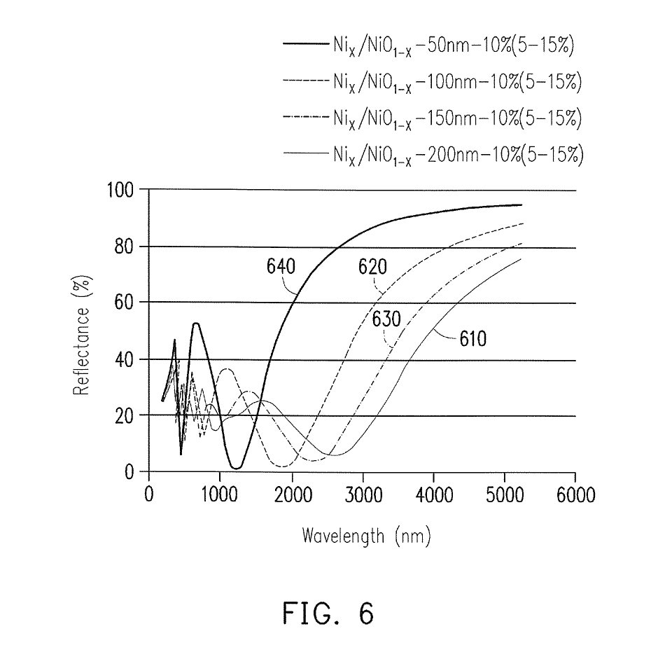

FIG. 6 illustrates a reflectance spectrum of Niₓ/NiO₁₋ₓ with a fixed metal volume fraction and changing film thicknesses according to the first exemplary embodiment of the disclosure. The range from low (L) metal volume fraction to high (H) metal volume fraction (LMVF %-HMVF %) is fixed to 5%-15%, and the film thicknesses of each layer are changed to from 50 nm to 200 nm, thereby obtaining four data curves 610, 620, 630 and 640, as shown in FIG. 6. With the same proportion of film metal volume fraction, the four data curves 610, 620, 630 and 640 all satisfy the characteristic of having high absorptivity in the wavelength range of 1.5 μm-3 μm. Therefore, as shown in Table 1, under the condition with the two-layer Niₓ/NiO₁₋ₓ, the range of film thickness of HMVF satisfying the disclosure is 50 nm˜200 nm and the range of film thickness of LMVF satisfying the disclosure is 50 nm˜200 nm.

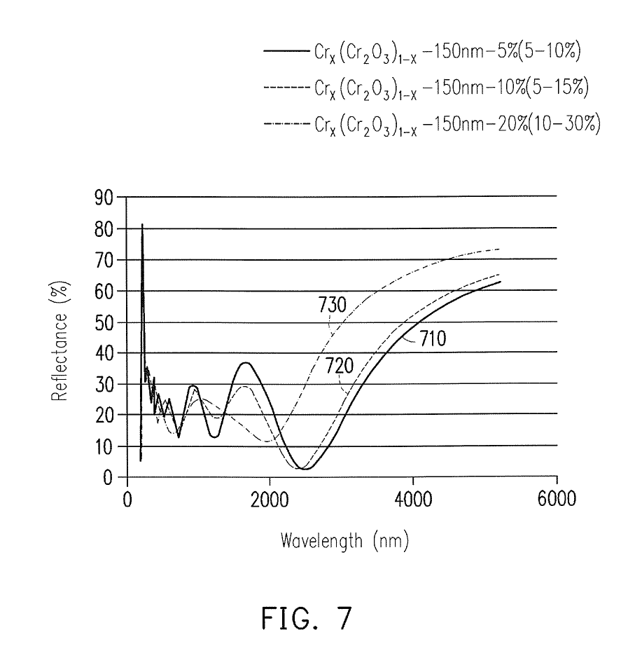

FIG. 7 illustrates a reflectance spectrum of Crₓ/(Cr₂O₃)₁₋ₓ with a fixed film thickness and changing metal volume fractions according to the first exemplary embodiment of the disclosure. The film thickness is fixed to 150 nm, and the range from low (L) metal volume fraction to high (H) metal volume fraction (LMVF %-HMVF %) is changed, thereby obtaining three data curves 710, 720 and 730, as shown in FIG. 7, wherein the ranges of metal volume fraction include, respectively, 5%-10%, 5%-15%, and 10%-30%. With the same film thickness, the three data curves 710, 720 and 730 all satisfy the characteristic of having high absorptivity in the wavelength range of 1.5 μm-3 μm. Therefore, as shown in Table 1, under the condition with the two-layer Crₓ/(Cr₂O₃)₁₋ₓ, the range of HMVF satisfying the disclosure is 10%-30% and the range of LMVF satisfying the disclosure is 5%-10%.

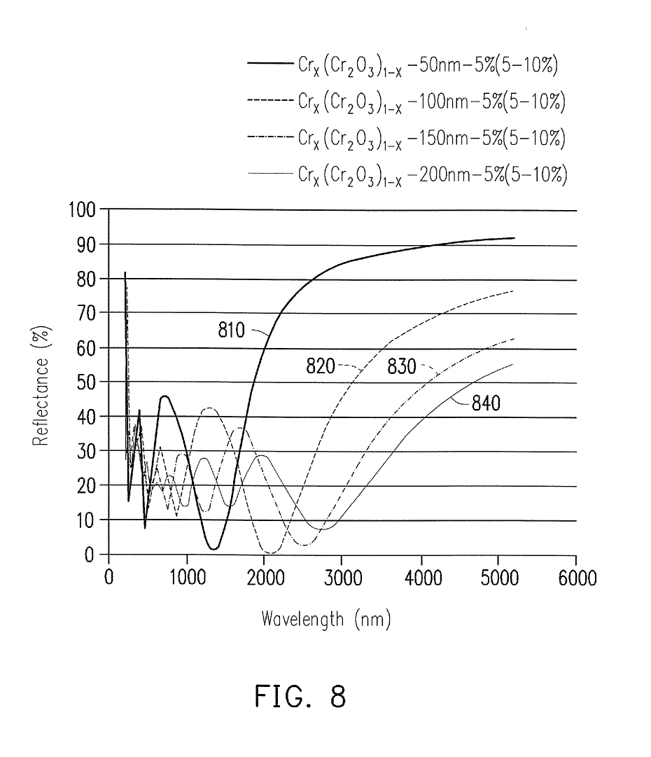

FIG. 8 illustrates a reflectance spectrum of Crₓ/(Cr₂O₃)₁₋ₓ with a fixed metal volume fraction and changing film thicknesses according to the first exemplary embodiment of the disclosure. The range from low (L) metal volume fraction to high (H) metal volume fraction (LMVF %-HMVF %) is fixed to 5%-10%, and the film thicknesses of each layer are changed to from 50 nm to 200 nm, thereby obtaining four data curves 810, 820, 830 and 840, as shown in FIG. 8. With the same proportion of film metal volume fraction, the four data curves 810, 820, 830 and 840 with the film thicknesses from 50 nm˜200 nm all satisfy the characteristic of having high absorptivity in the wavelength range of 1.5 μm-3 μm. Therefore, as shown in Table 1, under the condition with the two-layer Crₓ/(Cr₂O₃)₁₋ₓ, the range of film thickness of HMVF satisfying the disclosure is 50 nm˜200 nm and the range of film thickness of LMVF satisfying the disclosure is 50 nm˜200 nm.

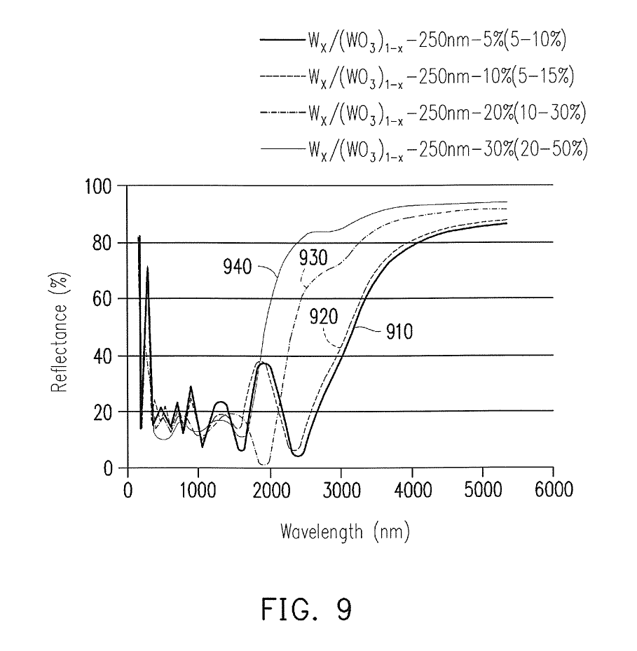

FIG. 9 illustrates a reflectance spectrum of Wₓ/(WO₃)₁₋ₓ with a fixed film thickness and changing metal volume fractions according to the first exemplary embodiment of the disclosure. The film thickness is fixed to 250 nm, and the range from low (L) metal volume fraction to high (H) metal volume fraction (LMVF %-HMVF %) is changed, thereby obtaining four data curves 910, 920, 930 and 940, as shown in FIG. 9, wherein the ranges of metal volume fraction include, respectively, 5%-10%, 5%-15%, 10%-30%, and 20%-50%. With the same film thickness, the four data curves 910, 920, 930 and 940 all satisfy the characteristic of having high absorptivity in the wavelength range of 1.5 μm-3 μm. Therefore, as shown in Table 1, under the condition with the two-layer Wₓ/(WO₃)₁₋ₓ, the range of HMVF satisfying the disclosure is 10%-50% and the range of LMVF satisfying the disclosure is 5%-20%.

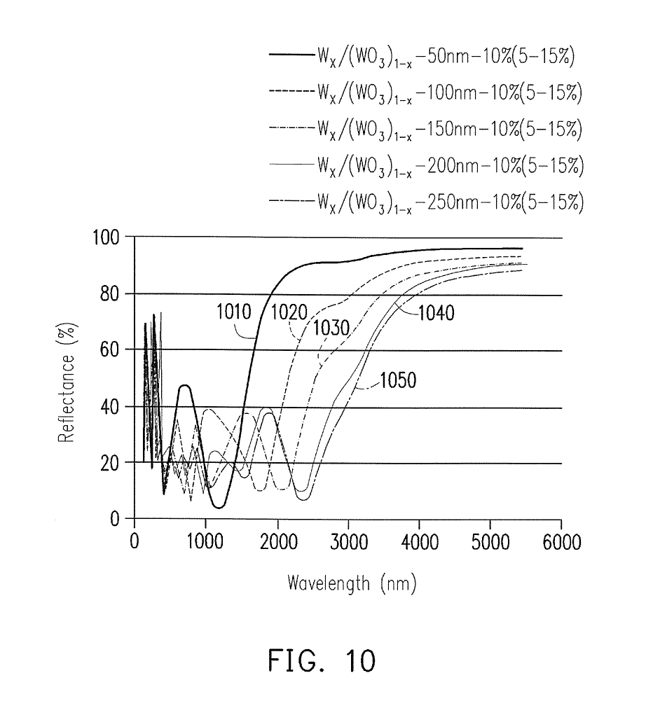

FIG. 10 illustrates a reflectance spectrum of Wₓ/(WO₃)₁₋ₓ with a fixed metal volume fraction and changing film thicknesses according to the first exemplary embodiment of the disclosure. The range from low (L) metal volume fraction to high (H) metal volume fraction (LMVF %-HMVF %) is fixed to 5%-15%, and the film thicknesses of each layer are changed to from 50 nm to 250 nm, thereby obtaining five data curves 1010, 1020, 1030, 1040 and 1050, as shown in FIG. 10. With the same proportion of film metal volume fraction, the five data curves 1010, 1020, 1030, 1040 and 1050 with the film thicknesses from 50 nm˜250 nm, all satisfy the characteristic of having high absorptivity in the wavelength range of 1.5 μm-3 μm. Therefore, as shown in Table 1, under the condition with the two-layer Wₓ/(WO₃)₁₋ₓ, the range of film thickness of HMVF satisfying the disclosure is 50 nm˜250 nm and the range of film thickness of LMVF satisfying the disclosure is 50 nm˜250 nm.

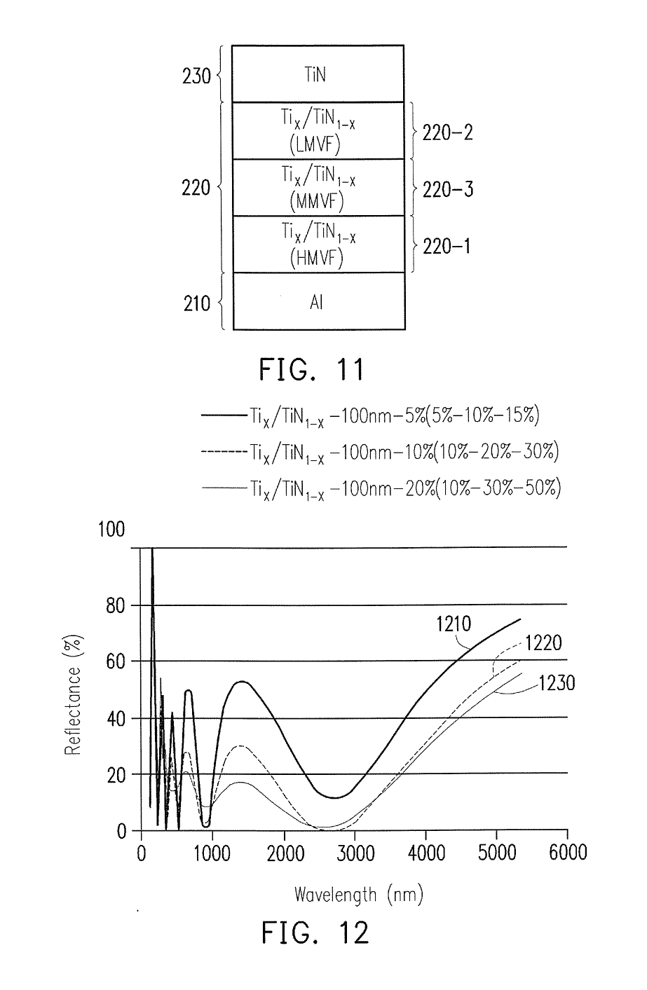

FIG. 11 is a cross-sectional diagram illustrating the selective absorber film 110 according to the second exemplary embodiment of the disclosure. The selective absorber film 110 of the present embodiment is different from that described in FIG. 2 in that in the selective absorber film 110 of the present embodiment, the cermet film 220 consists of a three-layer Tiₓ/TiN₁₋ₓ film, and Tiₓ/TiN₁₋ₓ films having a high (H) metal volume fraction, a medium (M) metal volume fraction and a low (L) metal volume fraction are employed as the cermet film 220, wherein the high metal volume fraction, the medium metal volume fraction and the low metal volume fraction have a gradient relationship. A Tiₓ/TiN₁₋ₓ film 220-1 having the high metal volume fraction is disposed on reflective substrate 210, a Tiₓ/TiN₁₋ₓ film 220-2 having the low metal volume fraction is disposed on the Tiₓ/TiN₁₋ₓ film 220-1 having the high metal volume fraction, and a Tiₓ/TiN₁₋ₓ film 220-3 having the medium metal volume fraction is disposed between the Tiₓ/TiN₁₋ₓ film 220-2 having the low metal volume fraction and the Tiₓ/TiN₁₋ₓ film 220-1 having the high metal volume fraction. In the present embodiment, the three-layer Tiₓ/TiN₁₋ₓ film is employed as the cermet film 220 of the selective absorber film 110, but does not intend to limit the disclosure.

TABLE 2

| | | Optimum | |
|---|---|---|---|
| Three-layer | | Range of Metal | Optimum Range of Film |
| Absorber Film | | Volume Fraction | Thickness of Each Layer |
| Tiₓ/TiN₁₋ₓ | LMVF | 5%~10% | 50 nm~100 nm |
| | MMVF | 10%~30% | 50 nm~100 nm |
| | HMVF | 15%~50% | 50 nm~100 nm |
| Niₓ/NiO₁₋ₓ | LMVF | 5%~10% | 50 nm~200 nm |
| | MMVF | 10%~30% | 50 nm~200 nm |
| | HMVF | 15%~50% | 50 nm~200 nm |
| Crₓ/(Cr₂O₃)₁₋ₓ | LMVF | 5%~10% | 50 nm~200 nm |
| | MMVF | 10%~30% | 50 nm~200 nm |
| | HMVF | 15%~50% | 50 nm~200 nm |
| Wₓ/(WO₃)₁₋ₓ | LMVF | 5%~10% | 50 nm~200 nm |
| | MMVF | 10%~30% | 50 nm~200 nm |
| | HMVF | 15%~50% | 50 nm~200 nm |

FIG. 12 illustrates a reflectance spectrum of Tiₓ/TiN₁₋ₓ with a fixed film thickness and changing metal volume fractions according to the second exemplary embodiment of the disclosure. The film thickness is fixed to 100 nm, and the range from low (L) metal volume fraction, medium (M) metal volume fraction to high (H) metal volume fraction (LMVF %-MMVF %-HMVF %) is changed, thereby obtaining three data curves 1210, 1220 and 1230, as shown in FIG. 12, wherein the ranges of metal volume fraction include, respectively, 5%-10%-15%, 10%-20%-30%, and 10%-30%-50%. With the same film thickness, the three data curves 1210, 1220 and 1230 all satisfy the characteristic of having high absorptivity in the wavelength range of 1.5 μm-3 μm. Therefore, as shown in Table 2, under the condition with the three-layer Tiₓ/TiN₁₋ₓ, the range of HMVF satisfying the disclosure is 15%-50%, the range of MMVF satisfying the disclosure is 10%-30%, and the range of LMVF satisfying the disclosure is 5%-10%.

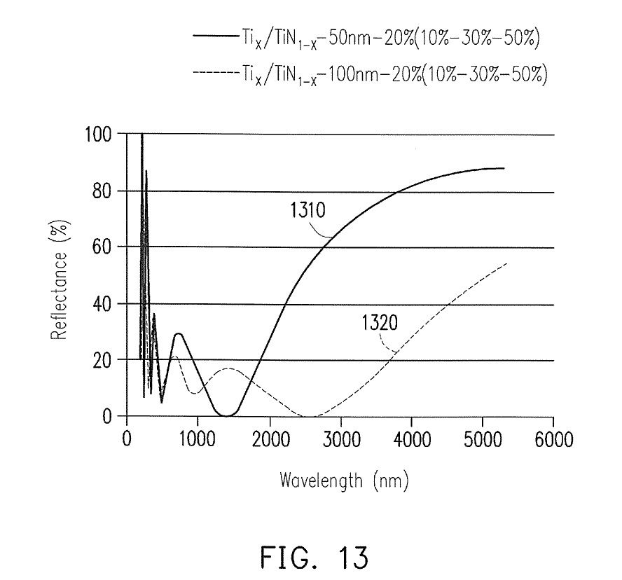

FIG. 13 illustrates a reflectance spectrum of Tiₓ/TiN₁₋ₓ with a fixed metal volume fraction and changing film thicknesses according to the second exemplary embodiment of the disclosure. The range from low (L) metal volume fraction, medium (M) metal volume fraction to high (H) metal volume fraction (LMVF %-MMVF %-HMVF %) is fixed to 10%-30%-50%, and the film thicknesses of each layer are changed to from 50 nm to 100 nm, thereby obtaining two data curves 1310 and 1320, as shown in FIG. 13. With the same proportion of film metal volume fraction, the two data curves 1310 and 1320 both satisfy the characteristic of having high absorptivity in the wavelength range of 1.5 μm-3 μm. Therefore, as shown in Table 2, under the condition with the three-layer Tiₓ/TiN₁₋ₓ, the range of film thickness of HMVF satisfying the disclosure is 50 nm˜100 nm, the range of film thickness of MMVF satisfying the disclosure is 50 nm˜100 nm, and the range of film thickness of LMVF satisfying the disclosure is 50 nm˜100 nm.

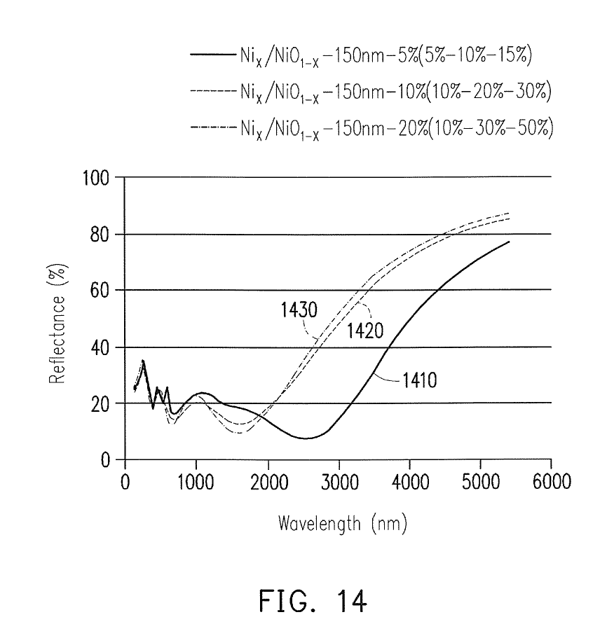

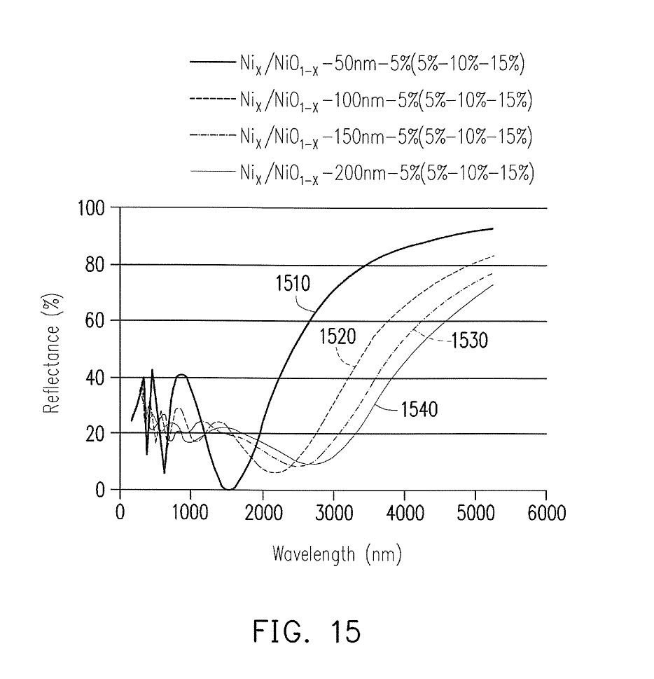

FIG. 14 illustrates a reflectance spectrum of Niₓ/NiO₁₋ₓ with a fixed film thickness and changing metal volume fractions according to the second exemplary embodiment of the disclosure. The film thickness is fixed to 150 nm, and the range from low (L) metal volume fraction, medium (M) metal volume fraction to high (H) metal volume fraction (LMVF %-MMVF %-HMVF %) is changed, thereby obtaining three data curves 1410, 1420 and 1430, as shown in FIG. 14, wherein the ranges of metal volume fraction include, respectively, 5%-10%-15%, 10%-20%-30%, and 10%-30%-50%. With the same film thickness, the three data curves 1410, 1420 and 1430 all satisfy the characteristic of having high absorptivity in the wavelength range of 1.5 μm-3 μin. Therefore, as shown in Table 2, under the condition with the three-layer Niₓ/NiO₁₋ₓ, the range of HMVF satisfying the disclosure is 15%-50%, the range of MMVF satisfying the disclosure is 10%-30%, and the range of LMVF satisfying the disclosure is 5%-10%.

FIG. 15 illustrates a reflectance spectrum of Niₓ/NiO₁₋ₓ with a fixed metal volume fraction and changing film thicknesses according to the second exemplary embodiment of the disclosure. The range from low (L) metal volume fraction, medium (M) metal volume fraction to high (H) metal volume fraction (LMVF %-MMVF %-HMVF %) is fixed to 5%-10%-15%, and the film thicknesses of each layer are changed to from 50 nm to 200 nm, thereby obtaining four data curves 1510, 1520, 1530 and 1540, as shown in FIG. 15. With the same proportion of film metal volume fraction, the four data curves 1510, 1520, 1530 and 1540 with the film thicknesses from 50 nm˜200 nm all satisfy the characteristic of having high absorptivity in the wavelength range of 1.5 μm-3 μm. Therefore, as shown in Table 2, under the condition with the three-layer Niₓ/NiO₁₋ₓ, the range of film thickness of HMVF satisfying the disclosure is 50 nm˜200 nm, the range of film thickness of MMVF satisfying the disclosure is 50 nm˜200 nm, and the range of film thickness of LMVF satisfying the disclosure is 50 nm˜200 nm.

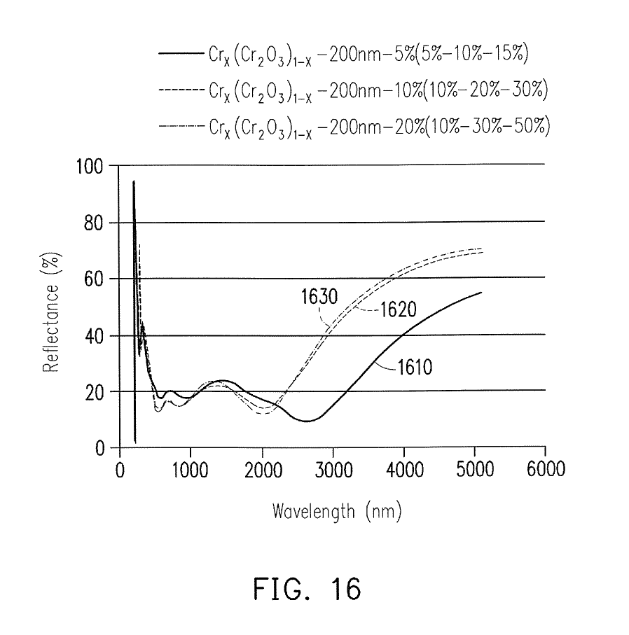

FIG. 16 illustrates a reflectance spectrum of Crₓ/(Cr₂O₃)₁₋ₓ with a fixed film thickness and changing metal volume fractions according to the second exemplary embodiment of the disclosure. The film thickness is fixed to 200 nm, and the range from low (L) metal volume fraction, medium (M) metal volume fraction to high (H) metal volume fraction (LMVF %-MMVF %-HMVF %) is changed, thereby obtaining three data curves 1610, 1620 and 1630, as shown in FIG. 16, wherein the ranges of metal volume fraction include, respectively, 5%-10%-15%, 10%-20%-30%, and 10%-30%-50%. With the same film thickness, the three data curves 1610, 1620 and 1630 all satisfy the characteristic of having high absorptivity in the wavelength range of 1.5 μm-3 μm. Therefore, as shown in Table 2, under the condition with the three-layer Crₓ/(Cr₂O₃)₁₋ₓ, the range of HMVF satisfying the disclosure is 15%-50%, the range of MMVF satisfying the disclosure is 10%-30%, and the range of LMVF satisfying the disclosure is 5%-10%.

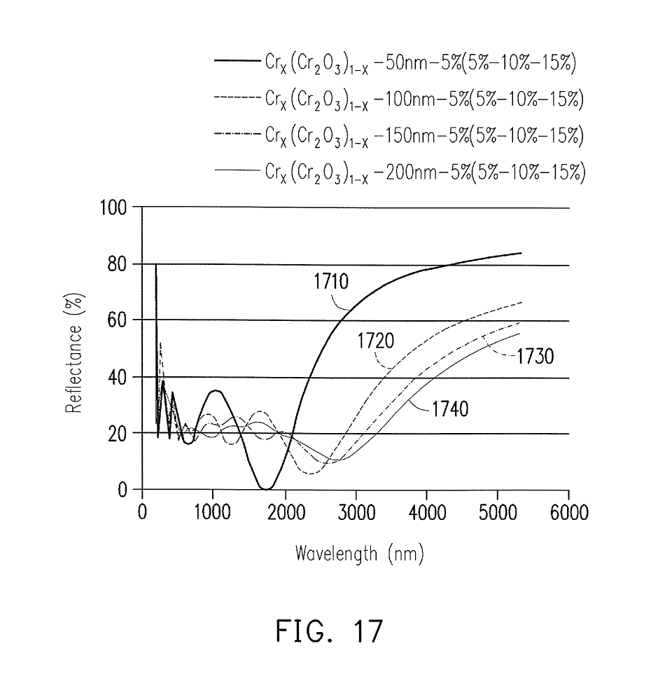

FIG. 17 illustrates a reflectance spectrum of Crₓ/(Cr₂O₃)₁₋ₓ with a fixed metal volume fraction and changing film thicknesses according to the second exemplary embodiment of the disclosure. The range from low (L) metal volume fraction, medium (M) metal volume fraction to high (H) metal volume fraction (LMVF %-MMVF %-HMVF %) is fixed to 5%-10%-15%, and the film thicknesses of each layer are changed to from 50 nm to 200 nm, thereby obtaining four data curves 1710, 1720, 1730 and 1740, as shown in FIG. 17. With the same proportion of film metal volume fraction, the four data curves 1710, 1720, 1730 and 1740 with the film thicknesses from 50 nm˜200 nm all satisfy the characteristic of having high absorptivity in the wavelength range of 1.5 μm-3 μm. Therefore, as shown in Table 2, under the condition with the three-layer Crₓ/(Cr₂O₃)₁₋ₓ, the range of film thickness of HMVF satisfying the disclosure is 50 nm˜200 nm, the range of film thickness of MMVF satisfying the disclosure is 50 nm˜200 nm, and the range of film thickness of LMVF satisfying the disclosure is 50 nm˜200 nm.

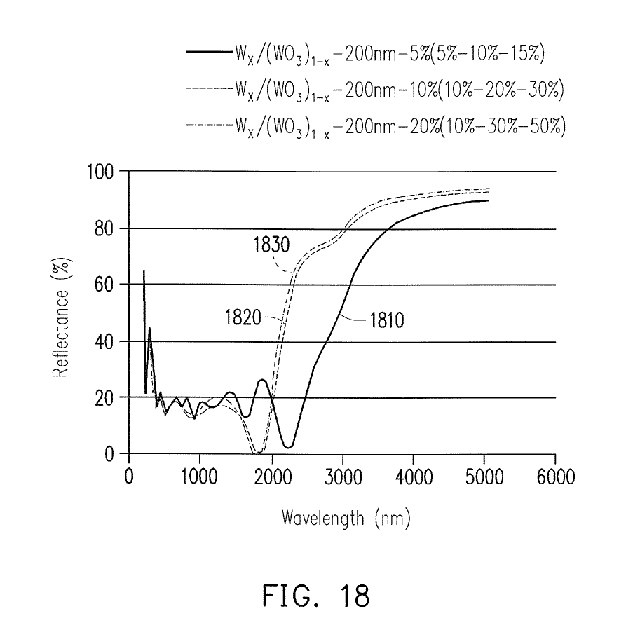

FIG. 18 illustrates a reflectance spectrum of Wₓ/(WO₃)₁₋ₓ with a fixed film thickness and changing metal volume fractions according to the second exemplary embodiment of the disclosure. The film thickness is fixed to 200 nm, and the range from low (L) metal volume fraction, medium (M) metal volume fraction to high (H) metal volume fraction (LMVF %-MMVF %-HMVF %) is changed, thereby obtaining three data curves 1810, 1820 and 1830, as shown in FIG. 18, wherein the ranges of metal volume fraction include, respectively, 5%-10%-15%, 10%-20%-30%, and 10%-30%-50%. With the same film thickness, the three data curves 1810, 1820 and 1830 all satisfy the characteristic of having high absorptivity in the wavelength range of 1.5 μm-3 μm. Therefore, as shown in Table 2, under the condition with the three-layer Wₓ/(WO₃)₁₋ₓ, the range of HMVF satisfying the disclosure is 15%-50%, the range of MMVF satisfying the disclosure is 10%-30%, and the range of LMVF satisfying the disclosure is 5%-10%.

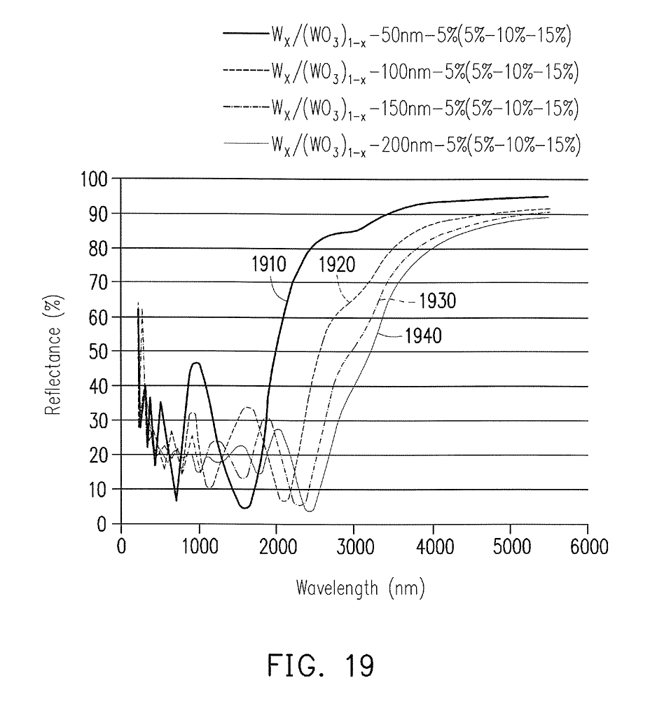

FIG. 19 illustrates a reflectance spectrum of Wₓ/(WO₃)₁₋ₓ with a fixed metal volume fraction and changing film thicknesses according to the second exemplary embodiment of the disclosure. The range from low (L) metal volume fraction, medium (M) metal volume fraction to high (H) metal volume fraction (LMVF %-MMVF %-HMVF %) is fixed to 5%-10%-15%, and the film thicknesses of each layer are changed to from 50 nm to 200 nm, thereby obtaining four data curves 1910, 1920, 1930 and 1940, as shown in FIG. 19. With the same proportion of film metal volume fraction, the four data curves 1910, 1920, 1930 and 1940 with the film thicknesses from 50 nm˜200 nm all satisfy the characteristic of having high absorptivity in the wavelength range of 1.5 μm-3 μm. Therefore, as shown in Table 2, under the condition with the three-layer Wₓ/(WO₃)₁₋ₓ, the range of film thickness of HMVF satisfying the disclosure is 50 nm˜200 nm, the range of film thickness of MMVF satisfying the disclosure is 50 nm˜200 nm and the range of film thickness of LMVF satisfying the disclosure is 50 nm˜200 nm.

In summary, the disclosure proposes a thermoelectric conversion device obtained by combining the thermoelectric conversion device with the selective absorber film and capable of adjusting the wavelength band in which heat radiation is absorbed. By the selective absorber film non-contactly absorbing different wavelength bands of heat radiation, the temperature of the hot terminal of the thermoelectric conversion device is increased which, in combination with the temperature of the cold terminal, causes a temperature difference for performing power generation, thus overcoming the conventional limitation that a heat source be contacted for power generation. In addition, the selective absorber film is connected with the P-type and N-type thermoelectric element materials to form electrical circuit loop, in which a ceramic substrate remains being used as the cold terminal, but may not be used as the hot terminal. In this way, problems associated with thermal resistance between the ceramic substrate and the thermoelectric materials and with thermal stress of the ceramic substrate are reduced, so that heat radiation utilization efficiency and life span of the thermoelectric conversion device are increased.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A thermoelectric conversion device, comprising:
at least one first selective absorber film for non-contactly absorbing a preset limited wavelength band of heat radiation;
a cold terminal substrate;
at least one first thermoelectric element pair disposed between the first selective absorber film and the cold terminal substrate, the first thermoelectric element pair comprising a first N-type thermoelectric element and a first P-type thermoelectric element;
a first conductive substrate disposed between the cold terminal substrate and the first N-type thermoelectric element; and
a second conductive substrate disposed between the cold terminal substrate and the first P-type thermoelectric element,
wherein the first thermoelectric element pair generates a current to perform power generation in response to temperature difference between the first selective absorber film and the cold terminal substrate.

2. The thermoelectric conversion device of claim 1, further comprising:
a second selective absorber film;
a second thermoelectric element pair disposed between the second selective absorber film and the cold terminal substrate, the second thermoelectric element pair comprising a second N-type thermoelectric element and a second P-type thermoelectric element; and
a third conductive substrate disposed between the second N-type thermoelectric element and the cold terminal substrate,
wherein the second conductive substrate is further disposed between the second P-type thermoelectric element and the cold terminal substrate.

3. The thermoelectric conversion device of claim 1, wherein the first selective absorber film comprises:
a reflective substrate;
a cermet film, comprising:
a first cermet composite film disposed on the reflective substrate, a metal volume fraction of the first cermet composite film falling within a range of 10% to 50%, a film thickness of the first cermet composite film falling within a range of 50 nm to 250 nm; and
a second cermet composite film disposed on the first cermet composite film, a metal volume fraction of the second cermet composite film falling within a range of 5% to 20%, a film thickness of the second cermet composite film falling within a range of 50 nm to 250 nm; and
an anti-reflection layer disposed on the second cermet composite film.

4. The thermoelectric conversion device of claim 3, wherein materials of a metal target of the cermet film comprise titanium, aluminum, stainless steel, copper, tungsten, nickel or chromium.

5. The thermoelectric conversion device of claim 3, wherein materials of the anti-reflection layer comprise a metal nitride or a metal oxynitride.

6. The thermoelectric conversion device of claim 5, wherein the materials of a metal target of the anti-reflection layer are the same as that of the cermet film.

7. The thermoelectric conversion device of claim 3, wherein materials of the reflective substrate comprise aluminum, copper, titanium or stainless steel.

8. The thermoelectric conversion device of claim 2, further comprising:
a heat dissipation device for performing heat dissipation on the cold terminal substrate; and
a power system electrically connected with the first conductive substrate and the third conductive substrate for performing power generation in response to the current.
